(19) United States
(12) Patent Application Publication
(10) Pub. No.: US 2005/0233560 A1
(43) Pub. Date: Oct. 20, 2005

(54) Silicon substrates with multi-grooved surface and production methods thereof

(75) Inventors: Hiroyuki Akinaga, Tsukuba-shi (JP); Zhi-Gang Sun, Tsukuba-shi (JP)

Correspondence Address: SEED INTELLECTUAL PROPERTY LAW GROUP PLLC, 701 FIFTH AVE, SUITE 6300, SEATTLE, WA, 98104-7092, US

(73) Assignee: National Institute of advanced Industrial Science and Technology, Chiyoda-ku (JP)

(21) Appl. No.: 11/084,083

(22) Filed: Mar. 17, 2005

(30) Foreign Application Priority Data
Mar. 17, 2004 (JP) 2004-075583

(51) Int. Cl. H01L 21/302

(52) U.S. Cl. 438/584; 148/33.3; 438/962

(57) ABSTRACT

Methods for producing silicon substrates that have a silicon surface layer with a high voidage are provided. These methods do not involve the use of hydrogen fluoride, and the silicon surface of these substrates has a voidage high enough to be regarded as defining a quantum wire. The methods for producing silicon substrates that have a surface layer with a high voidage comprise at least the steps of depositing a uniform metal coating on at least a part of the silicon substrate; immersing the coated silicon substrate in a treating solution comprising at least hydrochloric acid and nitric acid to etch the metal coated surface; recovering the silicon substrate from the treating solution after a predetermined time; and removing any part other than the region in which microgrooves are approximately uniformly distributed. Also provided are silicon substrates that have a surface layer with a high voidage which are produced by such methods.

### BACKGROUND OF THE INVENTION

1. Field of the Invention

The present invention relates to silicon substrates with a multi-grooved surface and production methods thereof. More specifically, it relates to silicon substrates which comprise, at least in part, a surface with approximately uniformly distributed microgrooves; where the grooves have been etched to such a degree that the edge of banks, which remain in mesa-like forms between the microgrooves, can be regarded as a quantum wire. The present invention also relates to methods for producing such silicon substrates.

2. Description of the Related Art

Highly porous silicon substrates are recently being used frequently as semiconductor substrates in various optical devices. This is because, due to having a cylindrical silicon structure remaining between the micropores, such silicon substrates exhibit a quantum confinement effect for charged carriers, which is highly comparable to the effect provided by quantum wires in superlattice structures or the like. Such a cylindrical silicon structure can be provided by the relatively convenient process of liquid phase etching. Such cylindrical silicon structures also have an increased band gap compared to single crystal silicon, enabling the use of optical effects such as photoluminescence in the visible light range.

The typical process for forming such a porous surface on a silicon substrate involves anodization of the silicon substrate in an aqueous solution of hydrogen fluoride, whereby the micropores formed in the surface are dilated until they reach a size sufficient enough to define a quantum wire, thereby forming silicon quantum wires. (See Japanese Patent No. 2611072.)

However, the process of anodizing silicon in an aqueous hydrogen fluoride solution to produce porous silicon is compromised by a high risk of damaging the silicon surface on which the lithographic pattern has been formed; and the inevitably prolonged exposure of the silicon surface to hydrogen fluoride results in the leakage of hydrogen fluoride around the sealed portion due to the geometry and defects of the silicon surface. Furthermore, this process also has demerits such as high system cost and low wafer throughput. (See Unexamined Published Japanese Patent Application No. (JP-A) Hei 6-13366, section of the “Prior Art”.)

### BRIEF SUMMARY OF THE INVENTION

As described above, a typical method for producing pores on a silicon surface involves anodization of the surface in an aqueous hydrogen fluoride solution. However, this process is compromised by safety issues associated with the use of a deleterious hydrogen fluoride as demonstrated in JP-A Hei 6-13366, and there are also concerns regarding the environmental impact of wastes produced by the treatment. For these reasons, the establishment of a method free from the use of hydrogen fluoride is highly anticipated.

In addition, dilatation of the pores to the degree required to define a quantum wire necessitates etching by anodization to a voidage as high as “78.5% or more” as demonstrated in Japanese Patent No. 2611072. This makes the substrate surface quite brittle, requiring complicated treatments, such as the use of a hetero structure by further coating the substrate with a material with a larger band gap, to make the substrate practical for use in a light emitting device, solar cell, or other optical device.

Furthermore, the increased voidage also reduces the area available for charge carrier injection, and hence, limits light emission efficiency, which greatly diminishes the practical utility of the device. Accordingly, establishment of (i) a new process to replace the conventional porosity-imparting process using hydrogen fluoride and (ii) microstructures to replace porous structures produced using such conventional processes is being much awaited also from the viewpoint of device designing.

The present inventors conducted an extensive study to establish such an etching process free from the use of aqueous hydrogen fluoride solutions, testing various treating solutions. As a result, they succeeded in establishing a process that does not involve the use of hydrogen fluoride, and also realized a structure of high voidage by distributing numerous microgrooves in place of micropores. A process capable of solving the technical problems as described above was thereby completed. The present invention is identified by the following technical features:

(1) A method for producing a silicon substrate comprising a high-voidage surface layer, wherein the method comprises at least the steps of:
(a) depositing a uniform metal coating on at least a part of the silicon substrate,
(b) etching the metal coated surface by immersing the coated silicon substrate in a treating solution comprising at least hydrochloric acid and nitric acid,
(c) recovering the silicon substrate from the treating solution after a predetermined time, and
(d) removing any part(s) other than the region in which microgrooves are approximately uniformly distributed.

(2) The method of (1), wherein the metal coating consists essentially of Fe₇₈Si₁₃B₉.

(3) The method of (2), wherein the metal coating consists essentially of a metal in which the Fe component is partially or entirely replaced with at least one element selected from the group consisting of Ti, V, Cr, Mn, Co, Ni, Cu, and Zn.

(4) The method of any one of (1) to (3), wherein the predetermined time of immersion is in the range of 2 to 600 seconds, when the metal coating has a thickness of 100 to 200 nm.

(5) The method of any one of (1) to (4), wherein a microgroove has a width of 0.5 to 1.0 μm, a depth of 100 to 300 nm, and a length of 1 μm or more.

(6) The method of any one of (1) to (5), wherein the region with approximately uniformly distributed microgrooves has a magnetic circular dichroism (MCD) peak in the wavelength range of 250 to 900 nm.

(7) The method of any one of (1) to (5), wherein the region with approximately uniformly distributed microgrooves comprises mesa-like banks remaining unetched between the microgrooves, and the banks have approximately uniform width and height and are approximately uniformly distributed in a planar direction.

(8) The method of any one of (1) to (7), which further comprises the step of depositing a magnetic material in the microgrooves.

(9) A silicon substrate that comprises a surface layer with a high-voidage, wherein the surface layer has etched microgrooves approximately uniformly distributed in a planar direction, and wherein the microgrooves are formed by immersing the substrate with a uniformly deposited metal coating, in a treating solution comprising at least hydrochloric acid and nitric acid, for a predetermined time.

(10) The silicon substrate of (9), wherein the metal coating consists essentially of Fe₇₈Si₁₃B₉.

(11) The silicon substrate of (10), wherein the metal coating consists essentially of a metal in which the Fe component is partially or entirely replaced with at least one element selected from the group consisting of Ti, V, Cr, Mn, Co, Ni, Cu, and Zn.

(12) The silicon substrate of any one of (9) to (11), wherein the predetermined time of immersion is in the range of 2 to 600 seconds when the metal coating has a thickness of 100 to 200 nm.

(13) The silicon substrate of any one of (9) to (12), wherein a microgroove has a width of 0.5 to 1.0 μm, a depth of 100 to 300 nm, and a length of not less than 1 μm.

(14) The silicon substrate of any one of (9) to (13), wherein the region with approximately uniformly distributed microgrooves has a magnetic circular dichroism (MCD) peak in the wavelength range of 250 to 900 nm.

(15) The silicon substrate of any one of (9) to (13), wherein the surface layer that has the approximately uniformly distributed microgrooves comprises silicon banks remaining unetched between the microgrooves in mesa-like forms, and the banks are approximately uniformly distributed in a planar direction and have approximately uniform width and height.

(16) The silicon substrate of any one of (9) to (15), wherein the microgrooves are filled with a magnetic material.

(17) The silicon substrate of any one of (9) to (15), wherein the substrate can be used in a visible light-emitting device.

(18) The silicon substrate of any one of (9) to (15), wherein the substrate can be used in a visible light-receiving device.

(19) The silicon substrate of any one of (9) to (15), wherein the substrate can be used in a solar battery.

(20) A silicon substrate for etching, comprising a uniform metal coating on at least one surface, wherein the metal coating consists essentially of Fe₇₈Si₁₃B₉.

(21) The silicon substrate of (20), wherein the metal coating consists essentially of a metal in which the Fe component is partially or entirely replaced with at least one element selected from the group consisting of Ti, V, Cr, Mn, Co, Ni, Cu, and Zn.

The expression “consisting essentially of” has been used in the description of the present invention to indicate that an error in the composition of about 2% at maximum is within the scope of the present invention, since such errors in the composition inevitably occur due to accuracy limitations of the film formation methods.

### BRIEF DESCRIPTION OF THE SEVERAL VIEWS OF THE DRAWINGS

FIG. 1 is a schematic view showing the solution treating apparatus of the present invention.

FIG. 2 is a graph showing the change in the composition of the substrate surface in relation to the time after immersion.

FIG. 3 is a photomicrograph of the substrate surface taken one second after the initial exposure of the silicon substrate.

FIG. 4 is a photomicrograph of the substrate surface taken five seconds after the initial exposure of the silicon substrate.

FIG. 5 is a photomicrograph of the substrate surface taken ten seconds after the initial exposure of the silicon substrate.

FIG. 6 is a photomicrograph of the substrate surface taken 30 seconds after the initial exposure of the silicon substrate.

FIG. 7 is a photomicrograph of the substrate surface taken 60 seconds after the initial exposure of the silicon substrate.

FIG. 8 shows photographs of the area where the microgroove structure is present, taken by an atomic force microscope ten seconds after the initial exposure of the silicon substrate.

FIG. 9 shows scanning electron micrograph (SEM) images of the area where microgrooves are present.

FIG. 10 is a graph showing the time course of photoluminescence intensity of the surface of the silicon substrate.

FIG. 11 shows photographs of photoluminescence for the area where microgrooves are present.

FIG. 12 shows the magnetic circular dichroism (MCD) of the surface layer of the silicon substrate at various immersion times.

### DETAILED DESCRIPTION OF THE INVENTION

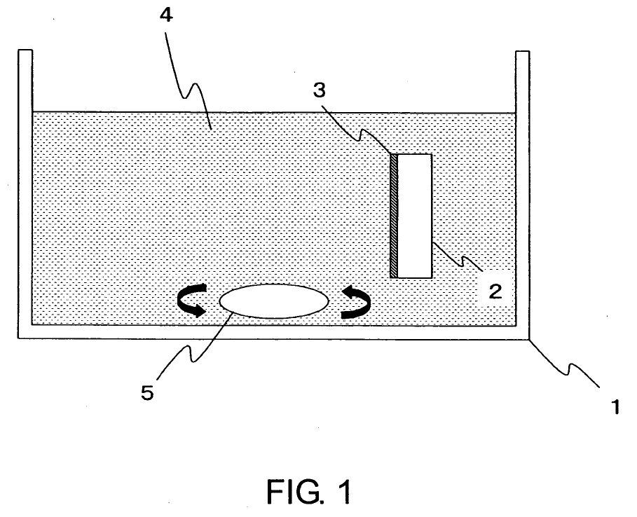

FIG. 1 shows an embodiment of the apparatus used for accomplishing the present invention. As shown in FIG. 1, a tank (1) is filled with a treating solution (4) comprising the so called “aqua regia” including given amounts of hydrochloric acid and nitric acid, and if desired, ethanol, and the like. A silicon substrate (2) to be treated is immersed and retained in the treating solution in the tank.

Microgroove formation takes place within the treating solution at the surface of the silicon substrate that has the metal coating layer (3). A stirrer (5) is placed in the treating solution, to maintain the uniformity of the treating solution by rotating the stirrer.

At least a part of the surface of the silicon substrate (2) has a metal material comprising Fe₇₈Si₁₃B₉ deposited to a thickness of 100 μm. The silicon substrate is immersed in the treating solution so that at least this metal-coated surface of the silicon substrate is exposed to the treating solution (electrolyte), and kept immersed for a predetermined time (i.e., 1 to 600 sec in this case).

The present invention enables the production of a surface that has a voidage high enough to define a quantum wire, without using aqueous hydrogen fluoride solutions. In addition, the present invention realized such a high voidage by approximately uniformly distributing numerous microgrooves, thus making it possible to replace a porous surface with the surface provided by the present invention, while containing surface strength decrease to a minimum.

Furthermore, since the high voidage structure realized by the microgroove distribution of the present invention is associated with directionality of the grooves in the direction of microgroove development, the silicon substrate surface can be imparted with a strong magnetic anisotropy when a magnetic material is deposited in the microgrooves.

Any patents, patent applications, and publications cited herein are incorporated by reference.

### EXAMPLES

### Example 1

The treating solutions used were HCl (40 ml), HCl (30 ml)+HNO₃ (10 ml), HCl (15 ml)+HNO₃ (5 ml)+H₂O (20 ml), and HCl (15 ml)+HNO₃ (5 ml)+ethanol (20 ml), and experiments were conducted by immersing a silicon substrate in each treating solution.

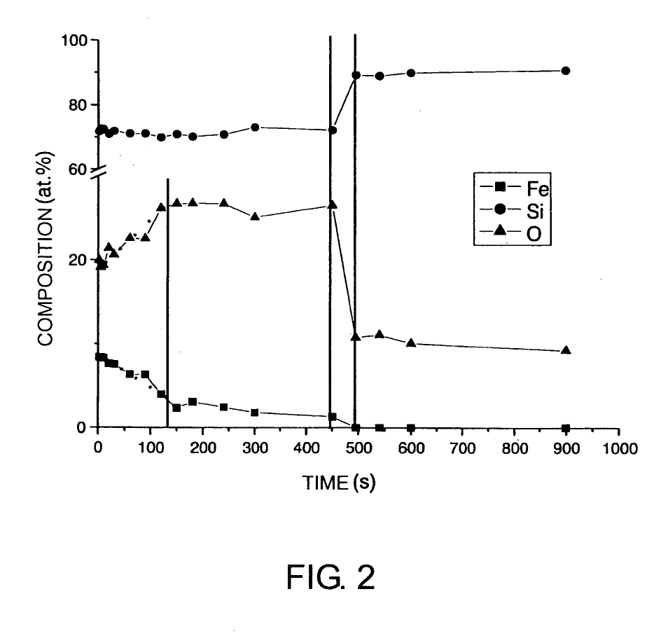

FIG. 2 shows a change in the substrate surface composition in relation to time when the silicon substrate was immersed in a treating solution comprising 3 HCl+HNO₃₊₄ Ethanol. Composition percentage (vertical axis) of Fe, Si, and O is respectively plotted against immersion time (horizontal axis). Erosion of the Fe₇₈Si₁₃B₉ coating layer was seen as indicated by the decrease of Fe after substrate immersion, and the silicon substrate started to become exposed at various locations about 130 seconds before the immersion. The exposed area started to expand immediately thereafter, and components such as Fe, which indicate the presence of the coating layer, completely disappeared at around 500 seconds.

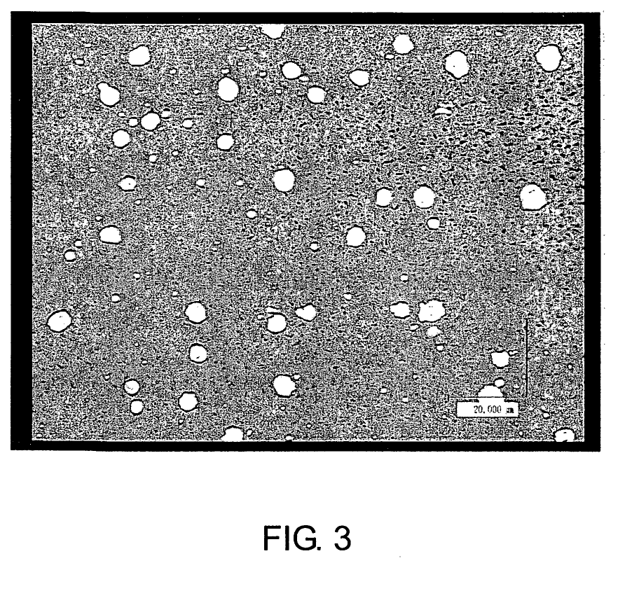

Coincidentally, etching with a treating solution comprising 3HCl+HNO₃ gradually changed the appearance of the substrate surface from brown to green and then to yellow, and the surface eventually showed a uniform silicon surface color. Photographs of the surface at 1, 5, 10, 30, and 60 seconds after initial exposure of the silicon substrate are shown in FIGS. 3 to 7, respectively.

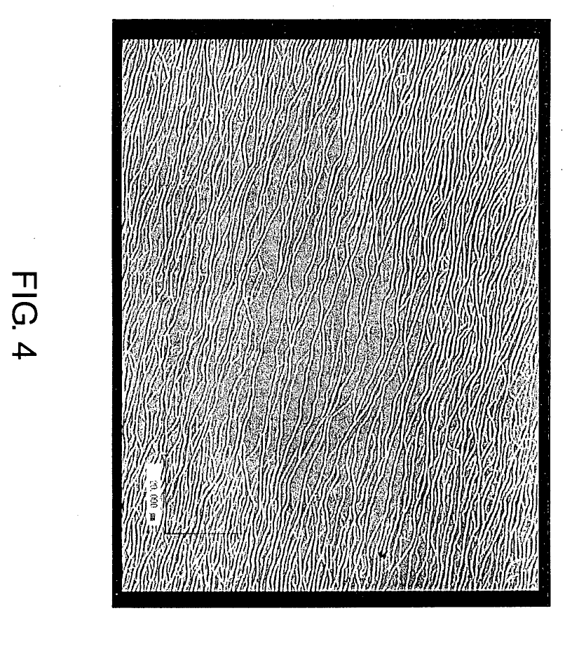

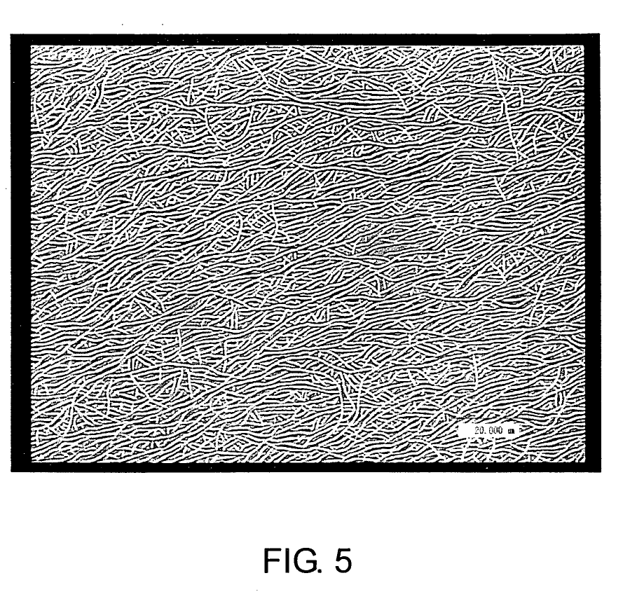

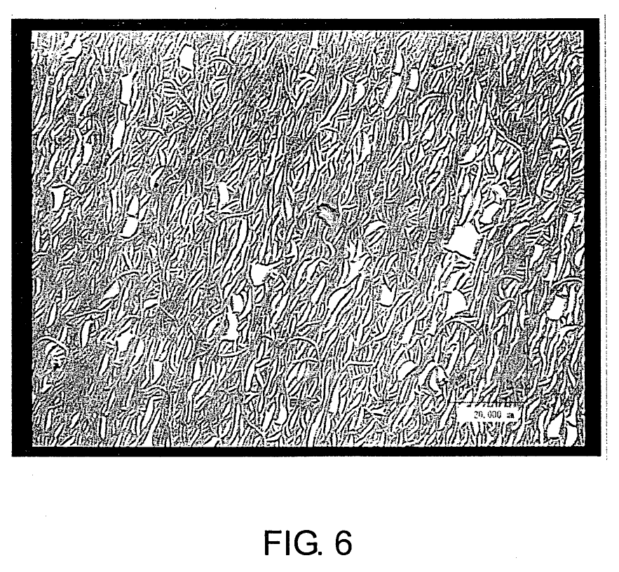

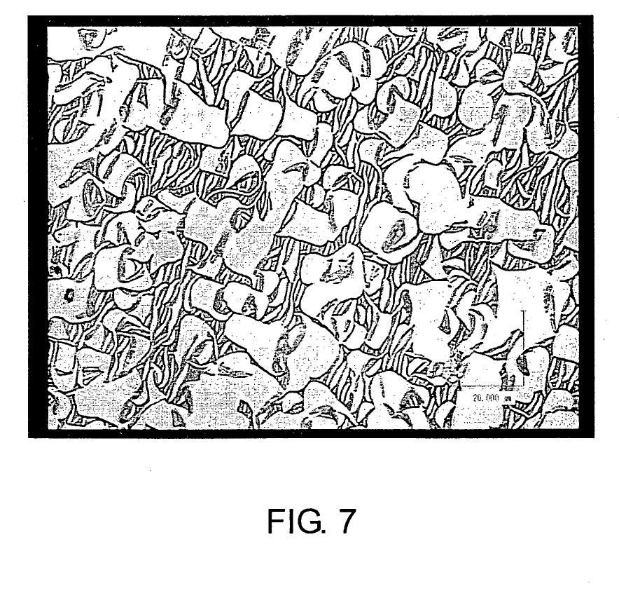

FIG. 3: one second after the initial exposure; shows circular flat silicon surface areas representing origins of exposure. FIG. 4: five seconds after the initial exposure; shows the exposed surface of the substrate covered with large groove-shaped structures radially extending from the origins of exposure. FIG. 5: ten seconds after the initial exposure; the large structures have divided into finer microgrooves that are approximately uniformly distributed. FIG. 6: 30 seconds after the initial exposure; the microgrooves appear to have integrated, forming a reticulated structure. FIG. 7: 60 seconds after the initial exposure: shows expansion of flat silicon surface areas. With continued immersion, almost the entire surface became a flat silicon substrate.

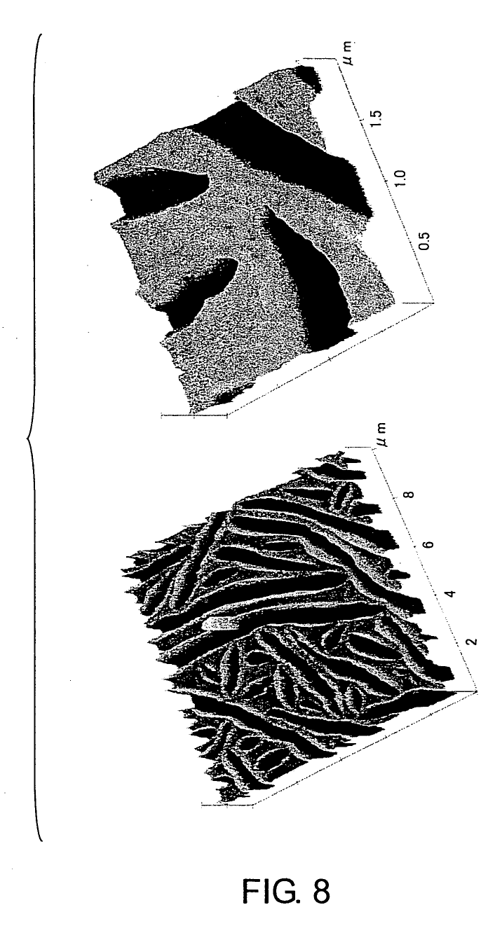

An area where the microgrooves were approximately uniformly distributed was selected and cut out from the silicon substrate at about 10 seconds after the initial exposure, and the surface of the cut out substrate was observed and photographed using an atomic force microscope (FIG. 8).

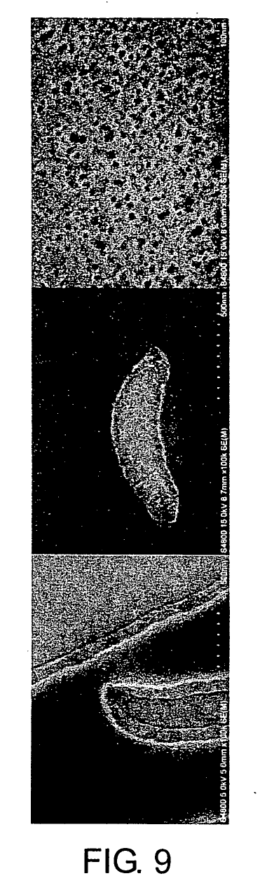

The microgrooves in the cut out substrate had the shape of eroded valleys with a width of about 200 to 500 nm and a depth of about 200 nm. Groove length was not less than 500 nm and longer grooves had a length in the order of millimeters. The uneroded parts were bank-like. FIG. 9, a photograph of a groove taken by a scanning electron microscope (SEM), indicates that the side-wall and the bottom of the groove have different characteristics. Since the erosion proceeds somewhat differently at various parts of the substrate surface, when selecting an area to cut off, it is preferable to choose an area between points where the exposure started at a relatively early timing and where microgrooves extend in relatively uniform directions.

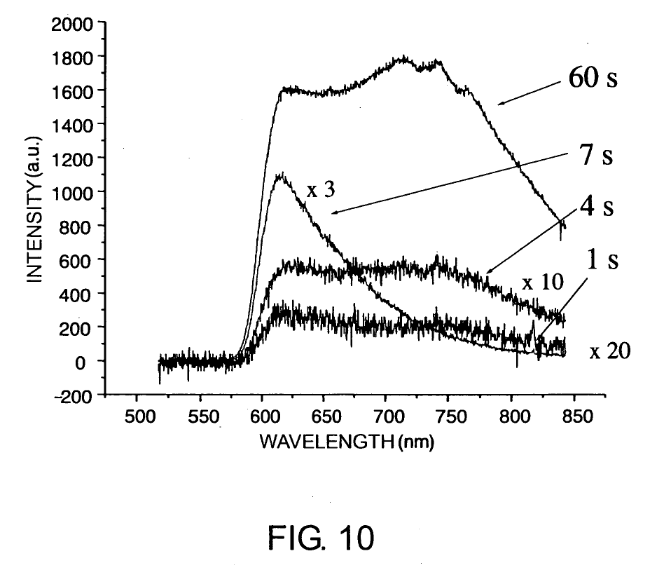

FIG. 10 shows photoluminescence at different degrees of etching. As shown in FIG. 10, a particularly strong light emission in the visible light range was found in the samples at seven to 60 seconds after the initial exposure. This light emission is believed to have been caused by the mesa-like banks that form quantum wire structures locally, as observed in the photographs taken by the atomic force microscope.

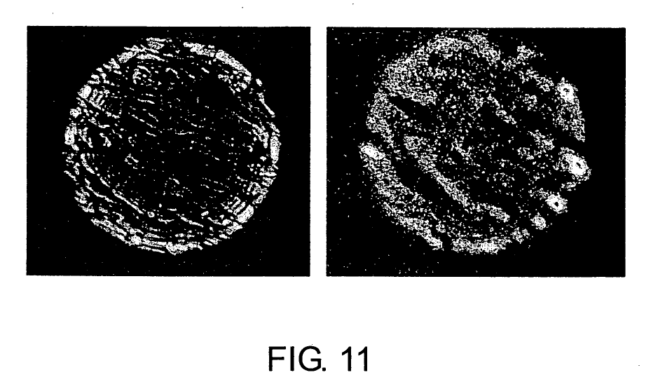

FIG. 11 consists of microphotographs showing light emission by photoluminescence. The areas of strong light emission in these photographs (the areas shown in a whitish color due to the black-and-white representation; would be shown in yellow in a color photograph) are concentrated along the longitudinal edges of the mesa-like banks, and this indicates that such edges have a fine structure that can be regarded as a quantum wire.

More specifically, mesa-like banks are structures that prevent three-dimensional isotropic extension of electron wave function. In particular, the longitudinal end of a mesa-like bank has a sharp-pointed structure in which the width gradually reduces towards the end, and the expansion of wave function is even more restricted. As a consequence, a mesa-like bank is presumed to have a structure resembling a quantum wire to a degree comparable to cylindrical silicon.

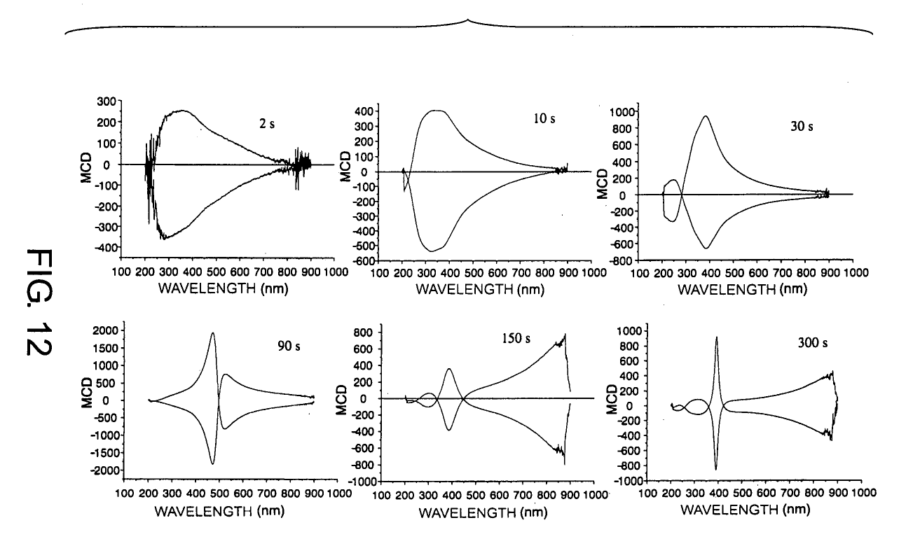

FIG. 12 shows effects of immersion time on magnetooptical properties. More specifically, FIG. 12 shows the measurements of magnetic circular dichroism (MCD) of the surface layer of the substrate at different immersion times, when the substrate is immersed in a treating solution comprising 3 HCl+HNO₃+4 Ethanol. In each graph, a curve that mainly shows a positive MCD was obtained when the applied magnetic field was positive, and a curve that mainly shows a negative MCD was obtained when the magnetic field applied was negative, and the substantial difference observed between these two curves indicates great magnetooptical effects of the sample. In addition to the peak wavelength of the magnetic circular dichroism (MCD), FIG. 12 also indicates that the measurements of the magnetic circular dichroism at each wavelength greatly vary over the entire wavelength measured (250 to 900 nm), depending on the immersion time.

In particular, the measurements at the immersion times of 150 sec and 300 sec in which the magnetic circular dichroism (MCD) does not converge to 0 on the longer wavelength side, indicate the possibility of using the magnetooptical effects at a wavelength longer than the wavelengths used in the measurement (i.e., the wavelength of up to 2000 nm).

The present invention is capable of providing silicon materials that have a surface layer with a high voidage. Such materials have useful applications as, for example, light-emitting materials that emit photoluminescence, and such.

The present invention is also capable of providing a method for producing silicon materials with a high voidage without using hydrogen fluoride in the solution-treating step (especially etching step), by employing, a system comprising metal coating and an aqua regia treating solution.

The present invention has realized a quantum wire structure by selecting an area in which microgrooves are approximately uniformly distributed, rather than dilating micropores. Therefore, the present invention provides methods for producing hetero structures and such with increased voidage and greater flexibility in subsequent steps.

The products of the present invention can also be adapted for use as device substrates in a wide range of optical systems, since magnetic circular dichroism (MCD) greatly varies at different immersion times. Desired magnetooptical properties are expected to be realized if the voidage increasing treatment of the present invention is carried out on a silicon substrate surface, using an immersion time appropriately suited for the wavelength of the optical system used.

The present invention is also capable of providing silicon substrates with a high voidage and a high magnetic anisotropy, by filling the microgrooves of a silicon substrate of the present invention with a magnetic material or the like.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A method for producing a silicon substrate comprising a high-voidage surface layer, wherein the method comprises at least the steps of:
(a) depositing a uniform metal coating on at least a part of the silicon substrate,
(b) etching the metal coated surface by immersing the coated silicon substrate in a treating solution comprising at least hydrochloric acid and nitric acid,
(c) recovering the silicon substrate from the treating solution after a predetermined time, and
(d) removing any part(s) other than the region in which microgrooves are approximately uniformly distributed.

2. The method of claim 1, wherein the metal coating consists essentially of Fe₇₈Si₁₃B₉.

3. The method of claim 2, wherein the metal coating consists essentially of a metal in which the Fe component is partially or entirely replaced with at least one element selected from the group consisting of Ti, V, Cr, Mn, Co, Ni, Cu, and Zn.

4. The method of claim 1, wherein the predetermined time of immersion is in the range of 2 to 600 seconds, when the metal coating has a thickness of 100 to 200 nm.

5. The method of claim 1, wherein a microgroove has a width of 0.5 to 1.0 μm, a depth of 100 to 300 nm, and a length of 1 μm or more.

6. The method of claim 1, wherein the region with approximately uniformly distributed microgrooves has a magnetic circular dichroism (MCD) peak in the wavelength range of 250 to 900 nm.

7. The method of claim 1, wherein the region with approximately uniformly distributed microgrooves comprises mesa-like banks remaining unetched between the microgrooves, and the banks have approximately uniform width and height and are approximately uniformly distributed in a planar direction.

8. The method of claim 1, which further comprises the step of depositing a magnetic material in the microgrooves.

9. A silicon substrate that comprises a surface layer with a high-voidage, wherein the surface layer has etched microgrooves approximately uniformly distributed in a planar direction, and wherein the microgrooves are formed by immersing the substrate with a uniformly deposited metal coating, in a treating solution comprising at least hydrochloric acid and nitric acid, for a predetermined time.

10. The silicon substrate of claim 9, wherein the metal coating consists essentially of Fe₇₈Si₁₃B₉.

11. The silicon substrate of claim 9, wherein the metal coating consists essentially of Fe₇₈Si₁₃B₉ and wherein the Fe component is partially or entirely replaced with at least one element selected from the group consisting of Ti, V, Cr, Mn, Co, Ni, Cu, and Zn.

12. The silicon substrate of claim 9, wherein the predetermined time of immersion is in the range of 2 to 600 seconds when the metal coating has a thickness of 100 to 200 nm.

13. The silicon substrate of claim 9, wherein a microgroove has a width of 0.5 to 1.0 μm, a depth of 100 to 300 nm, and a length of not less than 1 μm.

14. The silicon substrate of claim 9, wherein the region with approximately uniformly distributed microgrooves has a magnetic circular dichroism (MCD) peak in the wavelength range of 250 to 900 nm.

15. The silicon substrate of claim 9, wherein the surface layer that has the approximately uniformly distributed microgrooves comprises silicon banks remaining unetched between the microgrooves in mesa-like forms, and the banks are approximately uniformly distributed in a planar direction and have approximately uniform width and height.

16. The silicon substrate of claim 9, wherein the microgrooves are filled with a magnetic material.

17. The silicon substrate of claim 9, wherein the substrate can be used in a visible light-emitting device.

18. The silicon substrate of claim 9, wherein the substrate can be used in a visible light-receiving device.

19. The silicon substrate of claim 9, wherein the substrate can be used in a solar battery.

20. A silicon substrate for etching, comprising a uniform metal coating on at least one surface, wherein the metal coating consists essentially of Fe₇₈Si₁₃B₉.

21. A silicon substrate for etching, comprising a uniform metal coating on at least one surface, wherein the metal coating consists essentially of Fe₇₈Si₁₃B₉ and wherein the the Fe component is partially or entirely replaced with at least one element selected from the group consisting of Ti, V, Cr, Mn, Co, Ni, Cu, and Zn.
